(19) United States
(12) Patent Application Publication
(10) Pub. No.: US 2014/0285244 A1
(43) Pub. Date: Sep. 25, 2014

(54) POWER-ON CIRCUIT

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: HAI-QING ZHOU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/199,997

(22) Filed: Mar. 6, 2014

(30) Foreign Application Priority Data
Mar. 22, 2013 (CN) 2013100937556

(51) Int. Cl. H03K 17/22

(52) U.S. Cl. CPC H03K 17/22
USPC 327/143

(57) ABSTRACT

A power-on circuit is connected to a video graphics array (VGA) connector of a display, a power supply unit (PSU), and a super input output (SIO) chip of a motherboard. The power-on circuit includes first to fourth electronic switches. The VGA connector is connected to the first electronic switch. The first electronic switch is connected to the second electronic switch. The second electronic switch is respectively connected to the third electronic switch and the fourth electronic switch. The fourth electronic switch is connected to the SIO chip. The power-on circuit could power on the motherboard via the power button on the display.

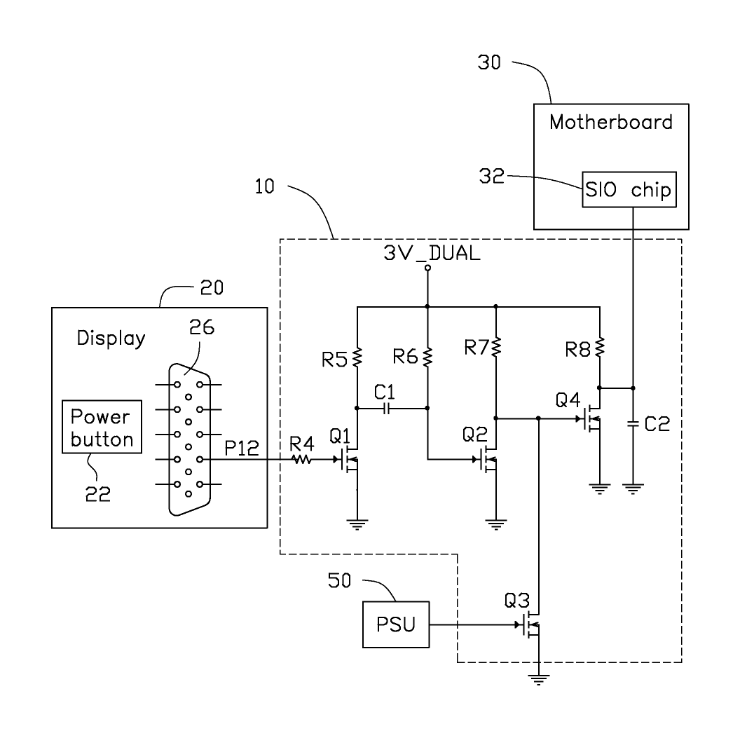

### BACKGROUND

1. Technical Field

The present disclosure relates to a power-on circuit.

2. Description of Related Art

Most desktop computers include a power button on a front panel of a chassis. However, most chassis are generally placed under computer desks. When one wants to power-on the desktop computer, one needs to bend over to press the power button, which is very inconvenient.

Therefore, there is room for improvement in the art.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the present disclosure. Moreover, in the drawing, like reference numerals designate corresponding parts throughout the several views.

The FIGURE is a circuit diagram of a power-on circuit, in accordance with an embodiment of the present disclosure.

### DETAILED DESCRIPTION

The disclosure, including the drawing, is illustrated by way of example and not by way of limitation. References to “an” or “one” embodiment in this disclosure are not necessarily to the same embodiment, and such references mean at least one.

The FIGURE shows an embodiment of the present disclosure of a power-on circuit 10. The power-on circuit 10 is connected to a display 20, a motherboard 30, and a power supply unit (PSU) 50. The power-on circuit 10 includes two capacitors C1 and C2, four electronic switches Q1-Q4, and five resistors R4-R8. The display 20 includes a power button 22 and a 15-pin video graphics array (VGA) connector 26. The motherboard 30 includes a super input output (SIO) chip 32.

Each of the electronic switches Q1-Q4 includes a first terminal, a second terminal, and a third terminal. The first terminal of the electronic switch Q1 is connected to a serial data line (SDA) pin P12 (namely the twelfth pin) of the VGA connector 26 through the resistor R4. The second terminal of the electronic switch Q1 is connected to a power supply 3V_DUAL through the resistor R5. The third terminal of the electronic switch Q1 is grounded. The first terminal of the electronic switch Q2 is connected to the second terminal of the electronic switch Q1 through the capacitor C1. The first terminal of the electronic switch Q2 is also connected to the power supply 3V_DUAL through the resistor R6. The second terminal of the electronic switch Q2 is connected to the power supply 3V_DUAL through the resistor R7. The third terminal of the electronic switch Q2 is grounded. The first terminal of the electronic switch Q3 is connected to the PSU 50 to receive a power good signal PWR_OK from the PSU 50. The second terminal of the electronic switch Q3 is connected to the second terminal of the electronic switch Q2. The third terminal of the electronic switch Q3 is grounded. The first terminal of the electronic switch Q4 is connected to the second terminal of the electronic switch Q2. The second terminal of the electronic switch Q4 is connected to the power supply 3V_DUAL through the resistor R8, and is connected to the SIO chip 32. The second terminal of the electronic switch Q4 is also grounded through the capacitor C2. The third terminal of the electronic switch Q4 is grounded.

According to the specification of a 15-pin video graphics array (VGA) connector, it may be understood that, the SDA pin P12 of the VGA connector 26 outputs a high level signal, such as logic 1, when the power button 22 is pressed to turn on the display 20, and the SDA pin P12 of the VGA connector 26 outputs a low level signal, such as logic 0, when the display 20 is turned off. According to the specification of a motherboard, when the SIO chip 32 receives a transient low level signal, the motherboard 30 is turned on, and after the motherboard 30 is turned on, the SIO chip 32 continues to receive a high level signal, and the motherboard 30 can operate normally.

When the power button 22 is pressed to turn on the display 20, the SDA pin P12 of the VGA connector 26 outputs a high level signal to turn on the electronic switch Q1. The electronic switch Q2 is turned off. When the motherboard 30 is turned off, the power good signal PWR_OK output from the PSU 50 is at a low level, the electronic switch Q3 is turned off, and the electronic switch Q4 is turned on. The SIO chip 32 receives a low level signal from the electronic switches Q4, and the motherboard 30 is turned on.

When the motherboard 30 is turned on, the power good signal PWR_OK output from the PSU 50 turns to a high level. The electronic switch Q3 is turned on, the electronic switch Q4 is turned off. The SIO chip 32 receives a high level signal regardless of whether the electronic switch Q3 is turned on or turned off. The motherboard 30 begins to operate.

When the display 20 is in the turned off state, the SDA pin P12 of the VGA connector 26 outputs a low level signal. The electronic switch Q1 is turned off, the electronic switch Q2 is turned on, the electronic switch Q4 is turned off, the SIO chip 32 does not receive a low level signal, and the motherboard 30 maintains a turned off state.

In one embodiment, each of the electronic switches Q1-Q4 is an n-channel field effect transistor (FET), and the first terminal, the second terminal, and the third terminal of each of the electronic switches Q1-Q4 are respectively a gate, a source, and a drain of the FET. In other embodiments, each of the electronic switches Q1-Q4 may be an npn bipolar junction transistor (BJT), or another switch having similar functions.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A power-on circuit connected to a video graphics array (VGA) connector of a display and a super input output (SIO) chip of a motherboard, the power-on circuit comprising:
a first resistor, a second resistor, a third resistor, and a fourth resistor;
a first electronic switch comprising a first terminal connected to a serial data line (SDA) pin of the VGA connector, a second terminal connected to a power supply through the first resistor, and a third terminal grounded;
a second electronic switch comprising a first terminal connected to the power supply through the second resistor, a second terminal connected to the power supply through the third resistor, and a third terminal grounded;
a third electronic switch comprising a first terminal connected to the second terminal of the second electronic switch, a second terminal connected to the power supply through the fourth resistor, and a third terminal grounded; and
a first capacitor connected between the second terminal of the first electronic switch and the first terminal of the second electronic switch;
wherein in response to a power button of the display being pressed to turn on the display, the SDA pin of the VGA connector outputs a high level signal, the first electronic switch is turned on, the second electronic switch is turned off, the third electronic switch is turned on, the SIO chip receives a low level signal from the third electronic switch, and the motherboard is turned on.

2. The power-on circuit of claim 1, further comprising a fourth electronic switch comprising a first terminal connected to a power supply unit (PSU) to receive a power good signal from the PSU, a second terminal connected to the second terminal of the second electronic switch, and a third terminal grounded; and wherein in response to the motherboard being turned on, the power good signal turns to a high level, the fourth electronic switch is turned on, the third electronic switch is turned off, the SIO chip receives a high level signal from the second terminal of the third electronic switch, the motherboard begins to operate.

3. The power-on circuit of claim 1, further comprising a fifth resistor, wherein the first terminal of the first electronic switch is connected to the SDA pin of the VGA connector through the fifth resistor.

4. The power-on circuit of claim 1, further comprising a second capacitor, wherein the second terminal of the third electronic switch is grounded through the second capacitor.

5. The power-on circuit of claim 1, wherein the first to third electronic switches are n-channel field effect transistors (FETs), the first to third terminals of the first to third electronic switches correspond to gates, sources, and drains of the FETs.

6. The power-on circuit of claim 2, wherein the fourth electronic switch is n-channel FET, the first to third terminals of the fourth electronic switch correspond to gates, sources, and drains of the FET.
